(19) United States
(12) Patent Application Publication
(10) Pub. No.: US 2009/0039463 A1
(43) Pub. Date: Feb. 12, 2009

(54) FUSE BOX AND METHOD FOR FABRICATING THE SAME AND METHOD FOR REPAIRING THE SAME IN SEMICONDUCTOR DEVICE

(75) Inventor: Jeong-Kyu KANG, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Kyoungki-do (KR)

(21) Appl. No.: 12/164,602

(22) Filed: Jun. 30, 2008

(30) Foreign Application Priority Data
Aug. 9, 2007 (KR) 10-2007-0079966

(51) Int. Cl. H01L 23/525; H01L 21/44

(52) U.S. Cl. 257/529; 438/102; 438/4; 257/E23.149; 257/E21.476

(57) ABSTRACT

A fuse box in a semiconductor device having a fuse line formed in a fuse line region to form a conductive pattern; wherein the conductive pattern has an empty space in the center thereof and a phase change material pattern in the empty space, and an insulation pattern formed over the fuse line to expose the phase change material pattern.

### CROSS-REFERENCE TO RELATED APPLICATIONS

The present invention claims priority of Korean patent application number 2007-0079966, filed on Aug. 9, 2007, which is incorporated by reference in its entirety.

### BACKGROUND OF THE INVENTION

The present invention relates to a method for fabricating a fuse box and a method for repairing the same in a semiconductor device.

Generally, when a flaw is detected in one of a plurality of cells in a semiconductor device, the semiconductor device cannot properly operate without performing a repair process to replace defective cells with normal cells.

The first step in the repair process is to determine if a cell has flaw. The semiconductor device uses a fuse box to pick out defective cells. The fuse box includes a plurality of fuse lines and stores data of defective cell address information according to connection states thereof. When an external address is inputted, the semiconductor memory device compares the external address information with the fail cell address information of the fuse box. Then, the memory device determines that the cells corresponding to the external address are fail cells and replaces them with other normal cells.

FIG. 1 illustrates a lay-out of a typical fuse box.

Referring to FIG. 1, the typical fuse box includes a plurality of fuse lines 11 and a plurality of isolation layers 12. The fuse lines 11 and the isolation layers 12 are alternately disposed in the fuse box. A guard ring 13 surrounds the fuse box in order to protect the fuse box.

In the typical method, a corresponding fuse line 11 is cut by laser to store the fail cell address information of the fuse box.

However, the typical repair process of cutting the fuse line has the following limitations. First, it is difficult to control a thickness of a remaining layer on the fuse line when the fuse box is formed. Second, errors can incur due to residual laser from cutting the fuse line. Third, the fuse line adjacent to the cut fuse line may be attacked. Furthermore, the cut portion can be oxidized and cracked. Thus, a reliability of the device decreases.

### SUMMARY OF THE INVENTION

Embodiments of the present invention are directed to providing a fuse box and a method for fabricating the same and a method for repairing the same in a semiconductor device. This invention overcomes diverse flaws that can occur during a repair process using a typical fuse cutting method, thereby increases reliability and throughput of the device.

In accordance with an aspect of the present invention, there is provided a fuse box in a semiconductor device having a fuse line formed in a fuse line region to form a conductive pattern; wherein the conductive pattern has an empty space in the center thereof and a phase change material pattern in the empty space; and, an insulation pattern formed over the fuse line to expose the phase change material pattern.

In accordance with another aspect of the present invention, there is provided a method for fabricating a fuse box in a semiconductor. The method includes providing a substrate; forming a conductive pattern in a fuse line region of the substrate; selectively etching a center portion of the conductive pattern to form an empty space therein, thereby forming a first resultant structure; forming a phase change material over the first resultant structure having the conductive pattern with the empty space therein, thereby forming a second structure; forming a phase change material pattern by patterning the phase change material to fill the empty space in the conductive pattern, thereby forming a third resultant structure; forming an insulation layer over the third resultant structure with the conductive pattern and phase change material pattern, and selectively etching the insulation layer to form an opening to expose the phase change material pattern.

In accordance with still another aspect of the present invention, there is provided a method for repairing a fuse box, which comprises a fuse line formed in a fuse line region to form a conductive pattern; wherein the conductive pattern has an empty space in the center thereof and a phase change material pattern in the empty space; and, an insulation pattern formed over the fuse line to expose the phase change material pattern. The method determines whether the fuse line is connected or not by radiating laser to the phase change material pattern to change a resistivity thereof.

### BRIEF DESCRIPTION OF THE DRAWINGS

FIG. 1 illustrates a lay-out of a typical fuse box.

FIG. 2 illustrates a lay-out of a fuse box in accordance with an embodiment of the present invention.

FIG. 3 illustrates a cross-sectional view of a semiconductor device employing the fuse box shown in FIG. 2 in accordance with a line A-A′.

FIGS. 4A to 4D are cross-sectional views describing a method for fabricating a semiconductor device with the fuse box shown in FIG. 2 in accordance with a line A-A′.

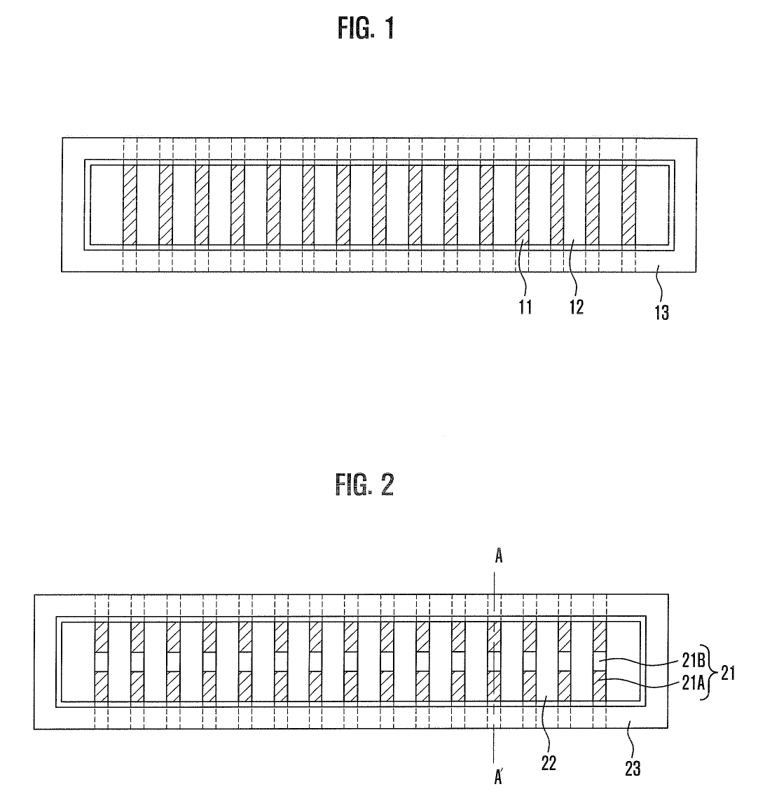

### DESCRIPTION OF SPECIFIC EMBODIMENTS

Embodiments of the present invention relate to a fuse box and a method for fabricating the same and a method for repairing the same in a semiconductor device.

FIG. 2 illustrates a lay-out of a fuse box in accordance with an embodiment of the present invention.

Referring to FIG. 2, the fuse box includes a plurality of fuse lines 21 and a plurality of isolation layers 22 formed in a fuse line region. The fuse lines 21 and the isolation layers 22 are alternately disposed in the fuse box. A guard ring 23 is formed to surround the fuse box and thereby protect the fuse box.

Each of the fuse lines 21 includes two kinds of material patterns, which are conductive patterns 21A and phase change material patterns 21B. The conductive patterns 21A are formed in a fuse line region in the fuse box to have an empty space in the center thereof. The phase change material patterns 21B are formed in the empty space.

Here, the phase change material is widely used for fabricating a phase change random access memory (PRAM) device. The phase change material detects the phase changes based on the temperature change of the phase change material. An amorphous-crystalline phase change material such as a germanium antimony telluride (GeSbTe, GST) layer is used in the present invention. Typically, an amorphous phase change material has a higher resistivity than a crystalline phase change material.

Accordingly, when the laser is radiated to one of the desired fuse lines 21 while the conductive patterns 21A are not electrically connected, by forming the amorphous phase change material pattern 21B in the empty space, the phase change material patterns 21B are changed from the amorphous phase to the crystalline phase. Thus, the resistivity of the phase change material patterns 21B decreases, thereby removing the empty spaces from the conductive patterns 21B. On the other hand, when the laser is radiated to one of the undesirable fuse lines 21A while the conductive patterns 21A are not electrically connected, by forming the crystalline phase change material pattern 21B, the phase change material patterns 21B are changed from the crystalline state to the amorphous phase. Thus, the resistivity of the phase change material pattern 21B increases, thereby separating the conductive patterns 21A.

As described, the amorphous-crystalline change is accomplished by adjusting the energy and the pulse width when the laser is beamed. That is, the fuse box changes the resistivity of the phase change material according to the fail cell address information. The fuse lines 21 are connected to the conductive patterns 21A to store the fail cell address information. Accordingly, when an external address is inputted, the semiconductor memory device compares the external address information with the fail cell address information of the fuse box. Then, the memory device determines whether the cells corresponding to the external address are fail cells and replaces them with normal cells if they are fail cells. Through the repair process described above, a lot of limitations that occurred during the repair process by cutting the fuse line can be thoroughly overcome.

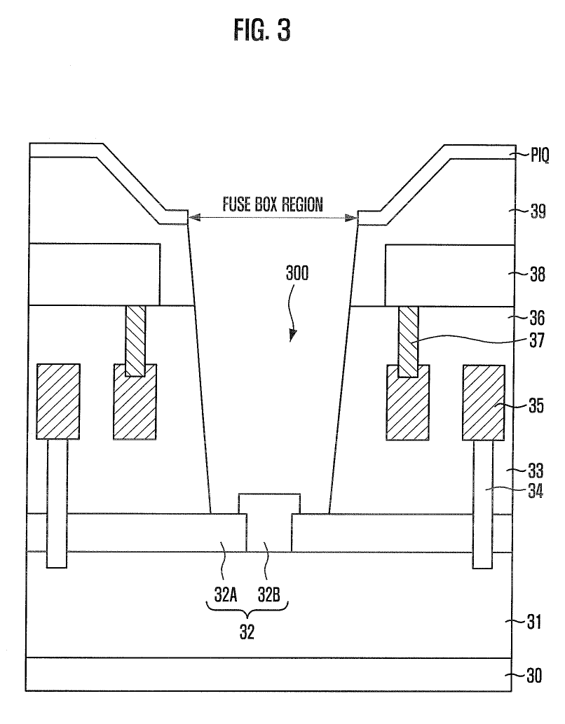

FIG. 3 illustrates a cross-sectional view of a semiconductor device employing a fuse box shown in FIG. 2 in accordance with a line A-A′.

Referring to FIG. 3, a first insulation layer 31 is formed over a substrate 30. A fuse line 32 is formed over the first insulation layer 31. The fuse line 32 includes a conductive pattern 32A having an empty space in the center thereof and a phase change material pattern 32B disposed in the empty space. The conductive pattern 32A is formed using a word line, a bit line, and a plate electrode in a cell region. Particularly, when the conductive pattern 32A is formed using the plate electrode, the conductive pattern 32A may include a stack structure of a polysilicon layer and a titanium (TiN) layer. The phase change material pattern 32B preferably includes aGST layer.

A stack structure of second to fourth insulation layers 33, 36, 39 and a passivation layer such as a polyimide isoind ro quinazoline (PIQ) layer is formed over the fuse line 32. This stack structure has an opening 300 exposing the phase change material pattern 32B and a portion of the adjacent conductive pattern 32A. Laser is radiated through the opening 300 to induce a phase change of the phase change material pattern 32B. Accordingly, the resistivity of the phase change material pattern 32B changes and it is possible to perform the repair process (refer to FIG. 2 and the description thereof).

A guard ring is formed outside the fuse box. The guard ring includes a first contact 34, a first metal line 35, a second contact 37, and a second metal line 38. The first contact 34 penetrates the second insulation layer 33 and fuse line 32. The first metal line 35 is formed over the second insulation layer 33 and connected to the fuse line 32 through the first contact 34. The second contact 37 is formed in the third insulation layer 36 over the first metal line 35. The second metal line 38 is formed over the third insulation layer 36 and connected to the second metal line 35 through the second contact 37. The guard ring surrounds the fuse box to protect it.

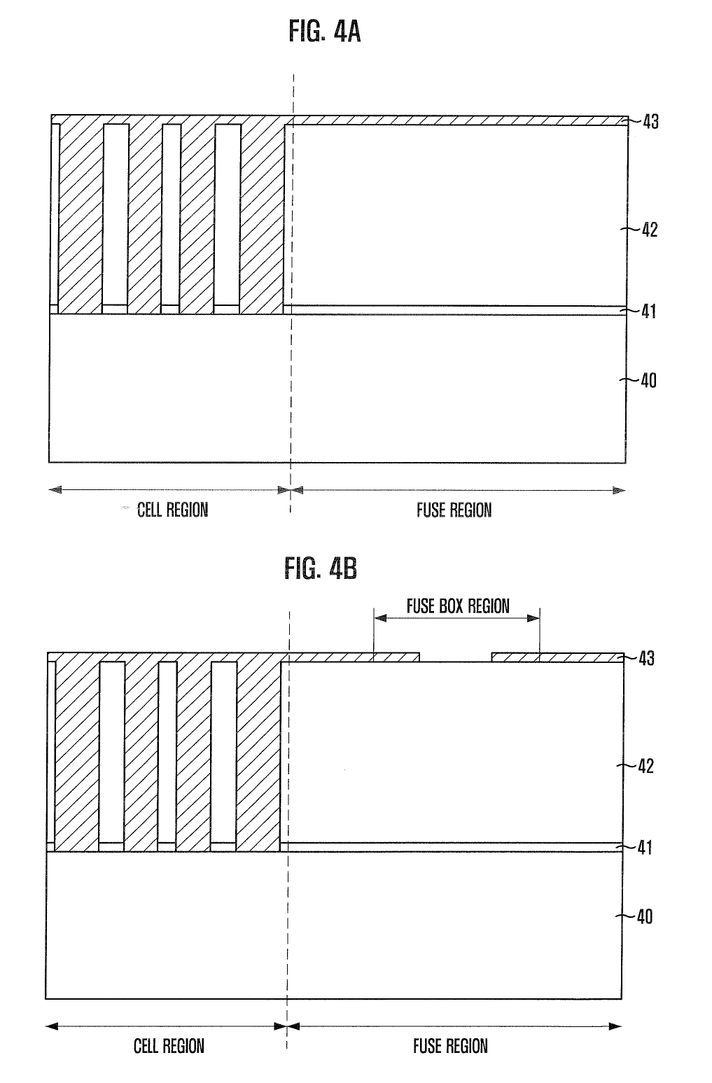

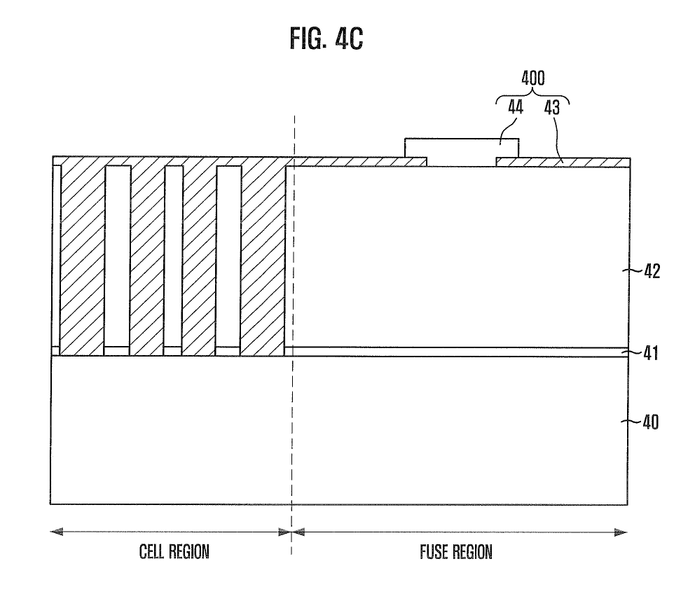

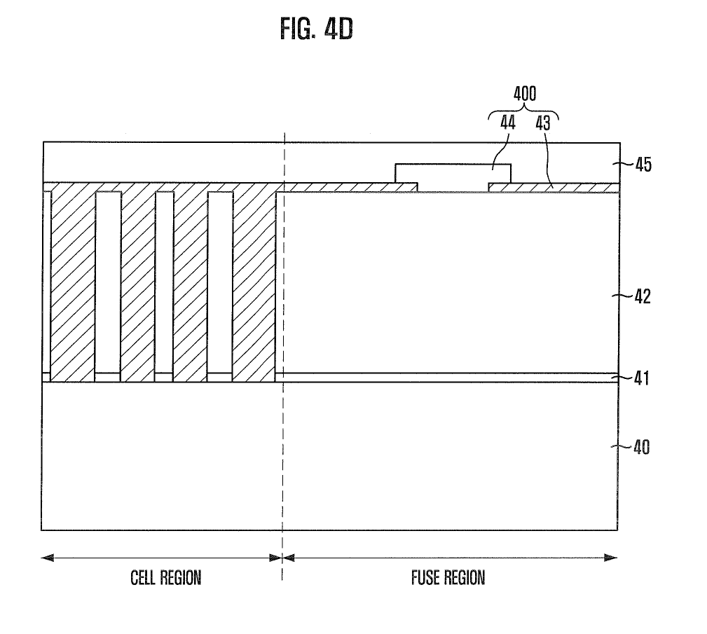

FIGS. 4A to 4D are cross-sectional views illustrating a method for fabricating a semiconductor device with the fuse box shown in FIG. 2 in accordance with a line A-A′. In this invention, the semiconductor device employs a cell region and a fuse region to form a fuse line using a plate electrode in the cell region.

Referring to FIG. 4A, etch stop layer 41 and first insulation layer 42 are formed over a substrate 40 where a predetermined lower structure is formed. A predetermined lower structure has a word line, a landing plug, a bit line, and a storage node contact therein.

The first insulation layer 42 and etch stop layer 41 are selectively etched to form a storage node hole exposing a predetermined portion of the substrate 40. Storage electrode (not shown) and dielectric layer (not shown) are formed over a resultant structure.

A plate electrode 43 is formed over a resultant structure. The plate electrode 43 may include a stack structure of a polysilicon layer and a TiN layer.

Referring to FIG. 4B, the plate electrode 43 in the fuse region is selectively etched to create an empty space in the plate electrode 43 in the center of the fuse box region.

Referring to FIG. 4C, a phase change material (e.g., a GST material) is formed over a resultant structure having the plate electrode 43 with an empty space in the center thereof and a patterning process is performed thereon. Thus, a phase change material pattern 44 filling the etched portion of the plate electrode 43 is formed. The phase change material pattern 44 preferably has greater width and height than the etched portion of the plate electrode 43 to secure an etch margin.

As a result, a fuse line 400 includes the plate electrode 43 having an empty space in the center thereof and phase change material pattern 44 disposed in the empty space.

Referring to FIG. 4D, a second insulation layer 45 is formed over a resultant structure including the fuse line 400. Although not shown, a subsequent process is performed to form the fuse box. That is, a first contact penetrating the second insulation layer 45 and fuse line 400 is formed outside the fuse box region.

A first metal line connected to the fuse line 400 through the first contact is formed over the second insulation layer and a third insulation layer covering the first metal line is formed thereon.

A second contact penetrating the third insulation layer outside the fuse box region is formed. A second metal line connected to the first metal line through the second contact is formed over the third insulation layer.

Fourth insulation layer and passivation layer are formed over the second metal line.

The passivation layer, fourth insulation layer, third insulation layer, and second insulation layer in the fuse box region are selectively etched to form an opening exposing the phase change material pattern 44. Thus, the fuse box can be formed. Since the process of etching of the passivation layer and the insulation layer is performed until the phase change material pattern 44 is exposed, a thickness of the remaining layer over the fuse line does not have to be controlled during the typical fuse formation process. Furthermore, the laser is radiated through the opening to cause a phase change of the phase change material pattern 44. Accordingly, the resistivity of the phase change material pattern changes and it is possible to perform the repair process.

As described above, the semiconductor device with the fuse of the present invention determines whether the desired fuse is connected or not based to the fail cell address information. Thus, typical equipment and process for cutting the fuse line are not required, thereby preventing occurrence of a flaw caused by cutting the fuse line.

In a repair process of the present invention, a fuse line is formed using a phase change material and a laser is radiated to induce an amorphous-crystalline change of the phase change material. Thus, a lot of limitations that occur during a typical repair process are thoroughly prevented, thereby increasing reliability and throughput of the device.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A fuse box in a semiconductor device, comprising:
a fuse line formed in a fuse line region to form a conductive pattern having an empty space in the center thereof and a phase change material pattern in the empty space; and
an insulation pattern formed over the fuse line to expose the phase change material pattern.

2. The fuse box of claim 1, wherein the phase change material pattern is a germanium antimony telluride (GeSbTe, GST) layer.

3. The fuse box of claim 1, wherein the conductive pattern is a plate electrode.

4. The fuse box of claim 1, wherein the phase change material pattern has greater width and height than the empty space in the conductive pattern.

5. A method for fabricating a fuse box in a semiconductor, comprising:
providing a substrate;
forming a conductive pattern in a fuse line region of the substrate;
selectively etching a center portion of the conductive pattern to form an empty space thereon to form a first resultant structure;
forming a phase change material over the first resultant structure including the conductive pattern with the empty space thereon to form a second structure;
forming a phase change material pattern by patterning the phase change material to fill the empty space in the conductive pattern thereon to form a third resultant structure;
forming an insulation layer over the third resultant structure including the conductive pattern and the phase change material pattern; and
selectively etching the insulation layer to form an opening exposing the phase change material pattern.

6. The method of claim 5, wherein the conductive pattern is a plate electrode.

7. The method of claim 5, wherein the phase change material pattern is a GST layer.

8. The method of claim 5, wherein-the phase change material pattern has greater width and height than the empty space in the conductive pattern

9. A method for repairing a fuse box, which comprises a fuse line formed in a fuse line region to form a conductive pattern having an empty space in the center thereof and a phase change material pattern in the empty space and an insulation pattern formed over the fuse line to expose the phase change material pattern, the method comprising:
determining whether the fuse line is connected or not by radiating a laser on the phase change material pattern to change a resistivity thereof.

10. The method of claim 9, wherein the phase change material pattern changes from an amorphous state to a crystalline state when the laser is radiated on it, thereby connect the fuse line.

11. The method of claim 9, wherein the phase change material pattern changes from a crystalline state to an amorphous state when the laser is radiated on it, thereby cut the fuse line.

12. The fuse box of claim 1, wherein the fuse box is protected by surrounding the fuse box with a guard ring.

13. The method of claim 5, wherein the fuse box is protected by surrounding the fuse box with a guard ring.

14. The method of claim 9, wherein the fuse box is protected by surrounding the fuse box with a guard ring.
